(19) United States
(12) Patent Application Publication
(10) Pub. No.: US 2008/0041067 A1
(43) Pub. Date: Feb. 21, 2008

(54) Thermoelectric conversion device and manufacture method of the same

(75) Inventors: Akio Matsuoka, Takahama-city (JP); Yasuhiko Niimi, Handa-city (JP); Yuji Ito, Okazaki-city (JP); Isao Kuroyanagi, Anjo-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/823,307

(22) Filed: Jun. 27, 2007

(30) Foreign Application Priority Data
Jun. 28, 2006 (JP) 2006-178307
Jan. 30, 2007 (JP) 2007-019952

(51) Int. Cl. H01L 35/30; H01L 23/38; H01L 35/32

(52) U.S. Cl. 62/3.7; 29/592.1

(57) ABSTRACT

A thermoelectric conversion device has a series circuit including P-type thermoelectric elements and N-type thermoelectric elements which are alternately arranged and connected with each other in series by electrode portions, heat-exchanging portions directly connected with the electrode portions, an insulating board from which the heat-exchanging portions protrude to be held and are electrically insulated, and an insulating layer which is electrically insulating and arranged at least a substantially whole surface of the protrusion side of the heat-exchanging portion. An adhesive layer covers exposure portions of the heat-exchanging portions from an outer side of the insulating layer. The exposure portions are exposed to a side of the heat transfer media.

### CROSS REFERENCE TO RELATED APPLICATION

This application is based on a Japanese Patent Application No. 2006-178307 filed on Jun. 28, 2006 and a Japanese Patent Application No. 2007-19952 filed on Jan. 30, 2007, the disclosure of which is incorporated herein by reference.

### FIELD OF THE INVENTION

The present invention relates to a thermoelectric conversion device and a manufacture method of the same.

### BACKGROUND OF THE INVENTION

Generally, with reference to JP-2006-93437A, a thermoelectric conversion device is provided with multiple N-type thermoelectric elements and multiple P-type thermoelectric elements which are alternately arrayed at an insulating substrate. Multiple heat-radiating electrode members are joined to the thermoelectric elements in such a manner that the heat-radiating electrode members protrude from the first end surfaces of the thermoelectric elements. Multiple heat-absorbing electrode members are joined to the thermoelectric elements in such a manner that the heat-absorbing electrode members protrude from the second end surfaces of the thermoelectric elements.

In this case, each of the heat-radiating electrode member and the heat-absorbing electrode member is constructed of a metal plate having a U-like shape, and provided with an electrode portion, a heat radiating portion and a heat absorbing portion. The electrode portion is joined to the P-type thermoelectric element and the N-type thermoelectric elements (which are adjacent to each other) at the bottom portion of the U-like shaped electrode member, to electrically connect the P-type thermoelectric element with the N-type thermoelectric element. The heat radiating portion and the heat absorbing portion protrude from the electrode portion.

Thus, the heat radiating portion and the heat absorbing portion are joined to the electrode portion without through an insulating layer, to improve a heat-exchanging efficiency of the thermoelectric conversion device.

However, in this case, when a voltage is applied to the series circuit constructed of the P-type thermoelectric element and the N-type thermoelectric elements, a short circuit and a migration will occur at the conductive parts of heat-radiating electrode member and the heat-absorbing electrode member and the like which are not insulated or where the insulation is not sufficient.

### SUMMARY OF THE INVENTION

In view of the above-described disadvantage, it is an object of the present invention to provide a thermoelectric conversion device where a short circuit and a migration are restricted, and a manufacture method of the thermoelectric conversion device.

According to a first aspect of the present invention, a thermoelectric conversion device has a series circuit including a plurality of P-type thermoelectric elements and a plurality of N-type thermoelectric elements which are alternately arranged and connected with each other in series by a plurality of electrode portions, a plurality of heat-exchanging portions for heat-exchanging with a heat transfer media, an insulating board from which the heat-exchanging portions protrude to be held, an insulating layer and an adhesive layer. The heat-exchanging portions are electrically insulated from each other by the insulating board. The heat-exchanging portions are directly connected with the electrode portions. The heat transfer media flows through protrusion sides of the heat-exchanging portions with respect to the insulating board. The insulating layer is electrically insulating and arranged at least a substantially whole surface of the protrusion side of each of the heat-exchanging portions. The heat-exchanging portions contact the insulating board, and the adhesive layer covers exposure portions of the heat-exchanging portions from an outer side of the insulating layer, the exposure portions being exposed to a side of the heat transfer media.

In this case, the insulating layer is arranged at the substantially whole surface of the heat-exchanging portion, thus restricting a short circuit due to the contact of the adjacent heat-exchanging portions and ion-migration which is caused by water droplet and the like adhered due to condensation when air is cooled.

Moreover, the heat-exchanging portions contact the insulating board, and the adhesive layer is arranged at the portion (such as exposure portion of heat-exchanging portion exposed to side of heat transfer media) where it is difficult to form the insulating layer. Thus, the insulation function can be improved to substantially restrict the short circuit and the ion-migration. Therefore, the reliability of the thermoelectric conversion device can be improved.

According to a second aspect of the present invention, a manufacture method for the thermoelectric conversion device is provided. The thermoelectric conversion device has a series circuit, an insulating board and a plurality of heat-exchanging portions for heat-exchanging with a heat transfer media flowing through protrusion sides of the heat-exchanging portions with respect to the insulating board. The manufacture method includes a module constructing step, an insulation layer forming step and an adhesive layer forming step. In the module constructing step, a thermoelectric conversion module is constructed to have the series circuit including a plurality of P-type thermoelectric elements and a plurality of N-type thermoelectric elements which are alternately arranged and connected with each other in series by a plurality of electrode portions directly connected with the heat-exchanging portions. The heat-exchanging portions protrude from the insulating board to be held and being electrically insulated from each other by the insulating board. In the insulation layer forming step, an insulating layer which is electrically insulating is formed at least a substantially whole surface of the protrusion side of each of the heat-exchanging portions. In the adhesive layer forming step, an adhesive layer is formed to cover exposure portions of the heat-exchanging portions from an outer side of the insulating layer. The exposure portion is exposed to a side of the heat transfer media, the heat-exchanging portions contacting the insulating board.

Thus, the thermoelectric conversion device having the above-described characteristics can be manufactured.

### BRIEF DESCRIPTION OF THE DRAWINGS

Other objects, features and advantages of the present invention will become more apparent from the following detailed description made with reference to the accompanying drawings, in which:

FIG. 1 is a schematic view showing a thermoelectric conversion device according to a first embodiment of the present disclosure;

FIG. 2 is a schematic view showing an arrangement of P-type thermoelectric elements and N-type thermoelectric elements of a thermoelectric element substrate unit when being viewed along the direction of arrow II in FIG. 1;

FIG. 3 is a schematic disassembled view showing the thermoelectric conversion device according to the first embodiment;

FIG. 4 is a schematic sectional view taken along a line IV-IV in FIG. 1;

FIG. 5 is a schematic enlarged sectional view of a V part in FIG. 4;

FIG. 6 is a schematic view showing an electrodeposition coating method according to the first embodiment;

FIG. 7 is a schematic view showing a thermoelectric conversion device according to a second embodiment of the present disclosure;

FIG. 8 is a schematic enlarged sectional view of a VIII part in FIG. 7;

FIG. 9 is a schematic view showing a thermoelectric conversion device according to a third embodiment of the present disclosure;

FIG. 10 is a schematic view showing a thermoelectric conversion device according to a fourth embodiment of the present disclosure;

FIG. 11 is a schematic enlarged sectional view of a XI part in FIG. 10;

FIG. 12 is a schematic view showing a thermoelectric conversion device according to a fifth embodiment of the present disclosure;

FIG. 13 is an enlarged schematic sectional view of a XIII part in FIG. 12; and

FIG. 14 is a schematic view showing a thermoelectric conversion device according to a sixth embodiment of the present disclosure.

### DETAILED DESCRIPTION OF THE EXAMPLED EMBODIMENTS

### First Embodiment

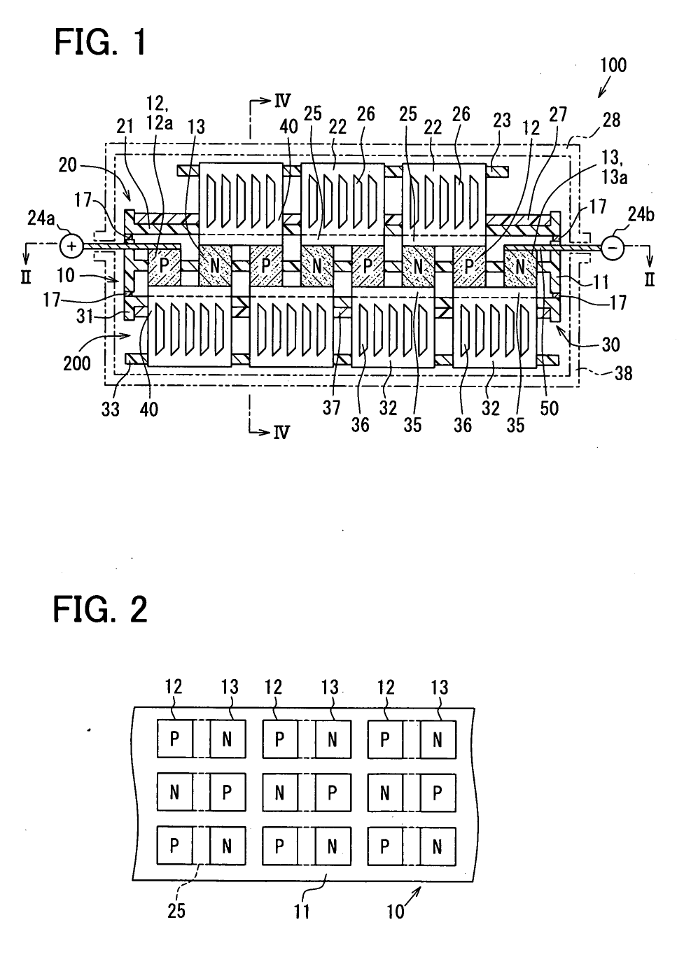

A thermoelectric conversion device 100 according to a first embodiment of the present invention will be described with reference to FIGS. 1-6.

As shown in FIG. 1, the thermoelectric conversion device 100 is provided with a thermoelectric element substrate unit 10 and a thermoelectric conversion module 200 which are housed in a case constructed of case members 28 and 38. The thermoelectric conversion module 200 has a heat-absorbing electrode board unit 20 and a heat-radiating electrode board unit 30.

With reference to FIGS. 1-4, the thermoelectric element substrate unit 10 has an insulating substrate 11 as a holding substrate and multiple thermoelectric element groups each of which includes a P-type thermoelectric element 12 and a N-type thermoelectric element 13. The insulating substrate 11 and the thermoelectric element groups are integrated with each other.

Specifically, the insulating substrate 11 is made of a substantially plate-shaped insulating material (for example, glass epoxy, phenol resin, PPS resin, LCP resin or PET resin). The insulating substrate 11 is provided with multiple engagement holes which are arrayed in a pattern of substantial lattice of uniform squares, for example. In the engagement hole, the P-type thermoelectric elements 12 and the N-type thermoelectric elements 13 are alternately arrayed.

The thermoelectric elements 12 (being minute component, for example) can be constructed of a P-type semiconductor comprised of Bi—Te compound (bismuth telluride compound). The thermoelectric element 13 (being minute component, for example) can be constructed of a N-type semiconductor comprised of Bi—Te compound. The two end surfaces (for example, upper end surface and lower end surface) of each of the thermoelectric elements 12 and 13 protrude from the insulating substrate 11. In this embodiment, the groups (totaling about 120, for example) each of which includes the thermoelectric elements 12 and 13 having a size of about 1.5 mm-squar are held at the insulating substrate 11.

As shown in FIGS. 1, 3 and 4, the electrode board unit 20 has multiple heat-absorbing electrode members 22, an insulating board 21 (first holding member) and a fixing member 23 (second holding member) which can be constructed of an insulating board. The heat-absorbing electrode members 22 are integrated with the insulating board 21 and the fixing member 23. The insulating board 21 and the fixing member 23 can have a plate shape, for example. The insulating board 21 is constructed of an insulating material (for example, glass epoxy, phenol resin, PPS resin, LCP resin or PET resin or the like).

The electrode board unit 30 has multiple heat-radiating electrode members 32, a third insulating board 31 (first holding member) and a fixing member 33 (second holding member) which can be constructed of an insulating board. The heat-radiating electrode members 32 are integrated with the third insulating board 31 and the fixing member 33. The insulating board 31 is constructed of a plate-shaped insulating material (for example, glass epoxy, phenol resin, PPS resin, LCP resin or PET resin or the like).

Specifically, each of the insulating board 21 and the fixing member 23 is provided with multiple engagement holes arrayed in a pattern of a substantial lattice of uniform squares. The multiple heat-absorbing electrode members 22 are held in the engagement holes.

Similarly, each of the insulating board 31 and the fixing member 33 has multiple engagement holes which are arranged in the pattern of the substantial lattice of uniform squares. The multiple heat-radiating electrode members 32 are held in the engagement holes.

In this case, the electrode members 22 and 32 are alternately arranged and arrayed in the pattern of the substantial lattice of uniform squares. The electrode members 22 and 32 are spaced from each other with a predetermined gap so that the electrode members 22 and 32 are electrically insulated to each other.

The electrode members 22 and 32 can be constructed of a thin plate material made of a conductive metal such as copper or the like, and shaped to have a U-like cross section as shown in FIG. 4. A bottom portion of the U-like electrode member 22 and that of the U-like electrode member 32 respectively construct a heat-absorbing electrode portion 25 and a heat-radiating electrode portion 35 (which have a substantial plate shape, for example).

Furthermore, the electrode members 22 and 32 are respectively provided with a heat exchanging portion 26 (heat absorbing portion) and a heat exchanging portion 36 (heat radiating portion). The heat exchanging portion 26, 36 extends outward from the electrode portion 25, 35, and has a louver. For example, the electrode member 22, 32 can be constructed of a plate material having a thickness of about 0.2 mm-0.3 mm, to have a desirable manufacture performance.

The electrode portion 25 of the electrode member 22 and the electrode portion 35 of the electrode member 32 are respectively joined (by soldering, for example) to the thermoelectric element 12 and the thermoelectric element 13 of the thermoelectric element substrate unit 10. Specifically, as shown in FIGS. 1, 3 and 4, the electrode member 22 is joined to the first end surfaces (e.g., upper end surfaces) of the thermoelectric element 12 and the thermoelectric element 13, and the electrode member 32 is joined to the second end surfaces (e.g., lower end surfaces) of the thermoelectric element 12 and the thermoelectric element 13.

The electrode portions 25 and 35 are electrodes for electrically connecting the thermoelectric element 12 with the thermoelectric element 13 which are adjacent to each other. Specifically, as shown in FIG. 1, the thermoelectric element 13 is connected with the thermoelectric element 12 by the electrode portion 25 in such a manner that the electrical current flows from the thermoelectric element 13 to the thermoelectric element 12 (which is adjacent to the thermoelectric element 13).

The thermoelectric element 13 is connected with the thermoelectric element 12 by the electrode portion 25 in such a manner that the electrical current flows from the thermoelectric element 12 to the thermoelectric element 13 (which is adjacent to the thermoelectric element 12). Thus, all of the thermoelectric elements 12 and 13 are connected with each other in series to construct a series circuit 50.

The heat exchanging portions 26 and 36 can be constructed of fins for transmitting heat absorbed/radiated through the electrode portions 25 and 35. In this case, heat can be absorbed through the heat exchanging portion 26 (heat absorbing portion) from fluid or the like contacting the heat exchanging portion 26, and heat can be radiated through the heat exchanging portion 36 (heat radiating portion) to fluid contacting the heat exchanging portion 36.

The heat exchanging portions 26 and 36 can be formed by respectively lancing the surfaces extending outward from the electrode portions 25 and 35, for example. In this embodiment, the heat exchanging portion 26 and the electrode portion 25 are integrated with each other to construct the electrode member 22, and the heat exchanging portion 36 and the electrode portion 35 are integrated with each other to construct the electrode member 32.

The electrode portion 25 of the electrode member 22 is constructed to slightly protrude from the insulating board 21 to the side of the thermoelectric element 12, and the heat exchanging portion 26 is not exposed to the side of the thermoelectric element 12. Similarly, the electrode portion 35 of the electrode member 32 is constructed to slightly protrude from the second insulating board 31 to the side of the thermoelectric element 13, and the heat exchanging portion 36 is not exposed to the side of the thermoelectric element 13.

The tip portions of the electrode members 22 and 32 are respectively held by the fix members 23 and 23. In this case, the tip portion of the electrode member 22 slightly protrudes from the upper surface of the fixing member 23, and tip portion of the electrode member 32 slightly protrudes from the lower surface of the fixing member 33.

The thermoelectric element 12 and the thermoelectric element 13 (respectively indicated by 12a and 13a) which are respectively arranged at two ends (of direction in which electrode members 22 and 32 are arrayed) of the series circuit 50 are respectively provided with connection terminals 24a and 24b. The series circuit 50 is constructed of the electrode portions 25 and 35 connected with each other.

The connection terminal 24a and the connection terminal 24b can be respectively connected with a positive terminal and a negative terminal of a direct-current power source (not shown).

According to the thermoelectric conversion module 200 described in this embodiment, when a voltage is applied to the connection terminal 24a, a direct current will flow in the series circuit 50 between the thermoelectric element 12a and the thermoelectric element 13a in such a manner that the direct current flows from the thermoelectric element 12a to the thermoelectric element 13 (which is adjacent to the thermoelectric element 12a) through the electrode portion 35 and further flows from the thermoelectric element 13 to the thermoelectric element 12 through the electrode portion 25.

In this case, the electrode portion 35 which is arranged at the PN joining portion has a high temperature state due to a Peltier effect, and the electrode portion 25 arranged at the NP joining portion has a low temperature state. Thus, the heat from the electrode portion 35 is transmitted to the heat exchanging portion 36 of the electrode member 32, and radiated to the cooling fluid (heat transfer media such as air) which contacts the heat exchanging portion 36. The heat absorbed from the electrode portion 25 is transmitted to the heat exchanging portion 26 of the electrode member 22, and absorbed by the cooling fluid (heat transfer media such as air) which contacts the heat exchanging portion 26.

Thus, as shown FIG. 1, the case members 28 and 38 respectively construct blown air passages (which are partitioned from each other by thermoelectric element substrate unit 10) at the two sides of the thermoelectric element substrate unit 10, that is, the side of the electrode member 22 and the side of the electrode member 32. Air (heat transfer media) flows through the blown air passage to heat-exchange with the heat exchanging portion 26 and the heat exchanging portion 36. Therefore, the air flowing through the passage of the side of the electrode member 22 is cooled and air flowing through the passage of the side of the electrode member 32 is heated.

In this case, the heat exchanging portions 26 and 36 of the thermoelectric conversion device 100 are respectively connected with the electrode portions 25 and 35, without being insulated from the electrode portions 25 and 35. The electrode portion 25 constructs a heat absorption portion of the series circuit 50, and the electrode portion 35 constructs a heat-radiation portion of the series circuit 50. Therefore, a heat-exchanging efficiency can be improved. However, when the voltage is applied to the connection terminal 24a and the connection terminal 24b, a potential is applied to the whole conductive part (heat exchanging portion 26, heat exchanging portion 36 and the like) which is connected with the series circuit 50 without being insulated. That is, the potential is not applied to only the series circuit 50, which is constructed of the thermoelectric elements 12 and 13.

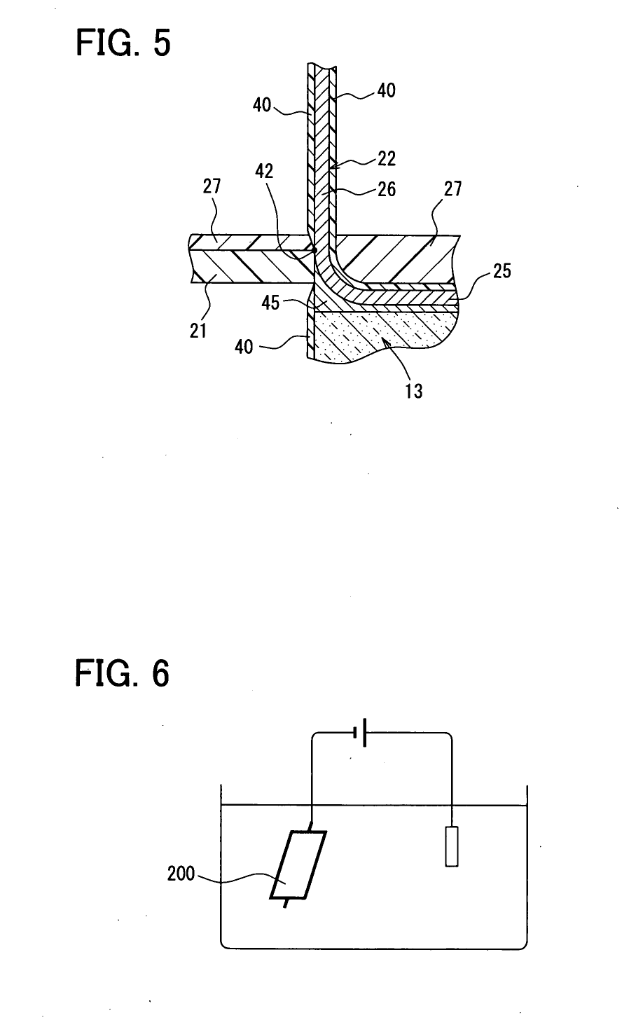

As shown in FIG. 5, in the thermoelectric conversion device 100, an insulating film 40 (insulating layer) for preventing a short circuit is arranged at the substantially whole surface of the conductive part, where the potential is applied when the voltage is applied to the connection terminal 24a and the connection terminal 24b of the thermoelectric conversion module 200.

The insulating film 40 can be formed by electrodeposition coating, for example. In this case, the electrodeposition coating can be performed before a process for sealing a gap 17 of the outer periphery of the thermoelectric conversion device 100 by an adhesive or the like. Thus, the insulating film 40 can be evenly formed at the substantial whole of the exposed surface of the conductive part (which is connected with series circuit 50 without being insulated) such as the surfaces of the heat exchanging portions 26 of the electrode member 22 and the heat exchanging portion 36 of the electrode member 32, the side surfaces of the thermoelectric element 12 and the thermoelectric element 13, the side surface of joining portions 45 (between electrode portion 25 and thermoelectric elements 12, 13 and between electrode portion 35 and thermoelectric elements 12, 13) and the like. The insulating film 40 is formed along the shape of this exposed surface of the conductive part.

Moreover, in the case where the electrodeposition coating is performed after the process for sealing the gap 17 of the thermoelectric conversion device 100, the insulating film 40 can be evenly formed at the whole surfaces of the heat exchanging portion 26 of the electrode member 22 and the heat exchanging portion 36 of the electrode member 32. In each of the case where the coating is performed before the sealing process and the case where the coating is performed after the sealing process, the insulating film 40 can insulate the conductive part (which is connected with series circuit 50 without being insulated). In this embodiment, the insulating film 40 can be formed by an epoxy resin coating, and provided with a film thickness of about 10 μm-20 μm, for example.

FIG. 5 shows the contact portion between the insulating board 21 and the electrode member 22 of the electrode board unit 20. In this case, the contact portion between the insulating board 31 and the electrode member 32 of the electrode board unit 30 can be provided with a substantially same construction as what is shown in FIG. 5.

Moreover, as shown in FIGS. 1 and 3-5, a first adhesive layer 27 and a second adhesive layer 37 are respectively formed at surfaces (which are at the opposite side to the thermoelectric element substrate unit 10) of the insulating board 21 and the third insulating board 31. As shown in FIG. 4, the adhesive layer 27 is formed at the substantially whole surface (of the side of heat exchanging portion 26) of the insulating board 21, to reach the inner side (i.e., back side of electrode portion 25) of the engagement portion of the electrode member 22 with the insulating board 21. The adhesive layer 37 is formed at the substantially whole surface (of the side of heat exchanging portion 36) of the insulating board 31, to reach the inner side (i.e., back side of electrode portion 35) of the engagement portion of the electrode member 32 with the insulating board 31. In this embodiment, the adhesive layer 27, 37 can be constructed of an epoxy resin adhesive or the like, and provided with a thickness of about 0.5 mm-1 mm, for example.

As shown in FIG. 5, the adhesive layer 27 is formed to cover the insulating film 40 from the outer side at the contact portion between the insulating board 21 and the heat exchanging portion 26 (root portion of the electrode member 22) and at an exposure portion 42 (exposed to side of air when being viewed at the stage before adhesive layer 27 is formed) of the heat exchanging portion 26. Similarly, the adhesive layer 37 is formed to cover the insulating film 40 from the outer side at the contact portion between the insulating board 31 and the heat exchanging portion 36 (root portion of the electrode member 33) and at the exposure portion 42 (exposed to side of air when being viewed at the stage before adhesive layer 37 is formed) of the heat exchanging portion 36.

Thus, because the adhesive layers 27 and 37 are provided, the insulation of the exposure portion 42 in the vicinity of the insulating substrates 21 and 31 where it is difficult for the insulating film 40 to be formed by the electrodeposition coating at the heat exchanging portions 26 and 36 can be reinforced. Moreover, the adhesive layers 27 and 37 are respectively filled into the gap between the insulating board 21 and the heat exchanging portion 26 and that between the insulating board 31 and the heat exchanging portion 36, to function as sealing materials which restricts intrusion of water or the like upon the side of the thermoelectric element substrate unit 10.

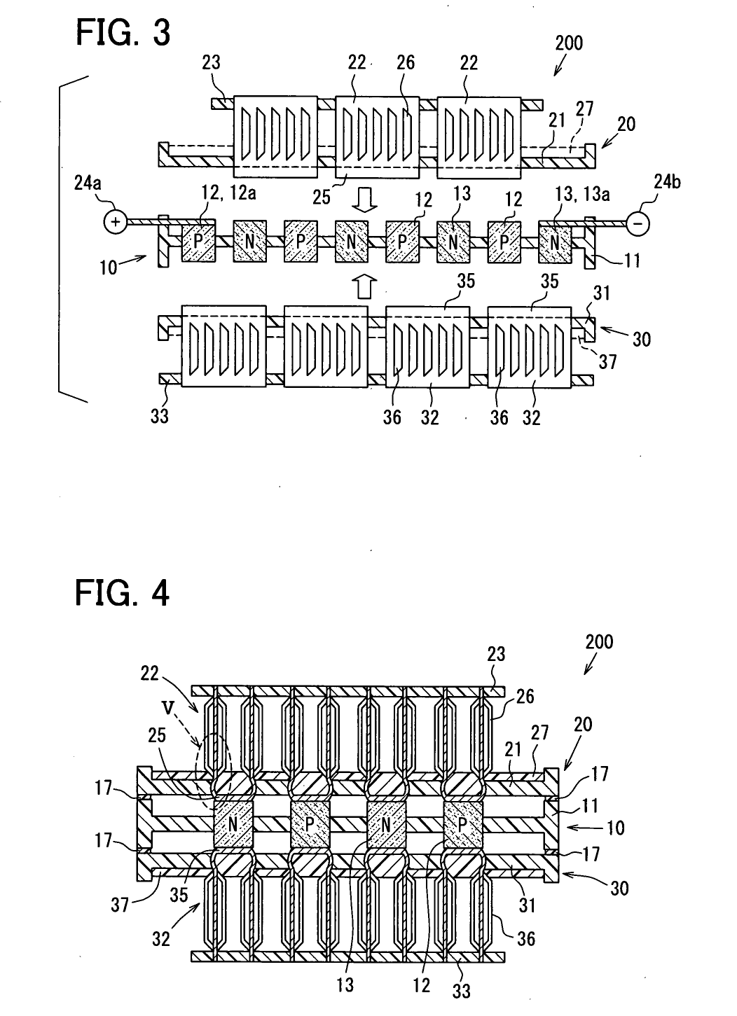

Next, the manufacture method of the thermoelectric conversion device 100 will be described. The manufacture method can include a module constructing step (shown in FIG. 3), an insulation layer forming step (shown in FIG. 6), and an adhesive layer forming step.

At the module constructing step, at first, the thermoelectric elements 12 and 13 are alternately arrayed and fixed by an adhesive or the like at the multiple engagement holes which are arrayed at the insulating substrate 11 in the pattern of the substantial lattice of uniform squares. Thus, the thermoelectric element substrate unit 10 is constructed. In this case, the attachment of the thermoelectric elements 12 and 13 to the insulating substrate 11 can be performed by using, for example, a mounter device which is a manufacture device for mounting semiconductor and electronic components to a control substrate.

On the other hand, the root portions of the electrode members 22 are engaged with the multiple holes which are formed at the insulating board 21 and arranged in the pattern of the substantial lattice of uniform squares, to be held in the holes. Moreover, the tip portions of the electrode members 22 are engaged with the engagement holes formed at the fixing member 23. Thus, the electrode board unit 20 is constructed.

Similarly, the root portions of the electrode members 32 are engaged with the multiple holes which are formed at the insulating board 31 and arranged in the pattern of the substantial lattice of uniform squares, to be held in the holes. Moreover, the tip portions of the electrode members 32 are engaged with the engagement holes formed at the fixing member 33. Thus, the electrode board unit 30 is constructed.

The electrode member 22 is arranged in such a manner that the electrode portion 25 of the electrode member 22 slightly protrudes from the insulating board 21. The electrode member 32 is arranged in such a manner that the electrode portion 35 of the electrode member 32 slightly protrudes from the insulating board 31.

Moreover, the tip portions of the electrode members 22 and 32 are respectively held in the engagement holes of the fixing member 23 and those of the fixing member 33. In this case, the tip portion of the electrode member 22 slightly protrudes from the upper surface (of opposite side of fixing member 23 to thermoelectric element substrate unit 10) of the fixing member 23, and the tip portion of the electrode member 32 slightly protrudes from the lower surface (of opposite side of fixing member 33 to thermoelectric element substrate unit 10) of the fixing member 33.

The electrode members 22 and 32 and can be beforehand formed. For example, the electrode member 22, 32 can be constructed of a metal plate material and manufactured by pressing process or the like to have a substantially U-like shape. The bottom portion of the U-like shape constructs the electrode portion 25, 35 having a substantial plate shape. The heat exchanging portions 26 and 36 having the louver shape respectively extends outward from the electrode portions 25 and 35.

Then, as shown in FIG. 3, the thermoelectric element substrate unit 10 is inserted between the electrode board unit 20 and the electrode board unit 30 to be assembled, so that the thermoelectric conversion module 200 is constructed. Specifically, the electrode portion 25 of the electrode member 22 is joined by soldering or the like to the upper end surface of the thermoelectric element 12 and the electrode portion 35 of the electrode member 32 is joined by soldering or the like to the lower end surface of the thermoelectric element 13, so that the thermoelectric elements 12 and 13 are respectively joined to the electrode members 22 and 32. In this case, a paste solder or the like can be thinly and evenly applied by screen printing to the upper surface of the thermoelectric element 12 and the lower surface of the thermoelectric element 13, and the electrode portions 25 and 35 are joined by soldering or the like to the thermoelectric elements 12 and 13.

For the thermoelectric conversion module 200 constructed as described above, at the insulation layer forming process, the insulating film 40 is formed (by electrodeposition coating) at the substantially whole surface of the conductive part, where a potential will be applied when a voltage is applied to the connection terminals 24a and 24b. Specifically, as shown in FIG. 6, the thermoelectric conversion module 200 is soaked in a sink where a solution of the epoxy resin paint is provided, and a voltage is applied to one (as negative pole) of the connection terminal 24a and the connection terminal 24b. After the paint is applied to the thermoelectric conversion module 200, the thermoelectric conversion module 200 is heated at a temperature about 180° c.-190° c., for example, so that the coating layer 40 (insulating film) is formed by baking the paint.

Thus, as shown in FIG. 5, the paint is selectively applied to the surface (for example, surfaces of electrode members 22 and 32, side surfaces of thermoelectric elements 12 and 13, side surface of solder joining portion 45 and the like) of the conductive part when the voltage is applied to the connection terminals 24a and 24b. As a result, the insulating film 40 (where pin holes can be restricted) is substantially evenly formed at the substantially whole surface of this conductive part. In this embodiment, the insulating film 40 having a thickness of about 10 μm-20 μm can be provided, for example.

In this embodiment, the voltage can be applied to the one (as negative pole) of the connection terminal 24a and the connection terminal 24b of the thermoelectric conversion module 200 when the electrodeposition coating is performed. Alternatively, the electrodeposition coating can be similarly performed with the voltage being applied at any position, if this position is in the conductive part where a potential is applied when a voltage is applied to the connection terminals 24a and 24b of the thermoelectric conversion module 200.

Moreover, in this embodiment, the electrodeposition coating is performed with applying the voltage to the thermoelectric conversion module 200 as the negative pole. Alternatively, the voltage can be also applied to the thermoelectric conversion module 200 as a positive pole in response to the used paint.

Next, at the adhesive layer forming process, the adhesive layer 27 and the adhesive layer 37 are respectively formed at the surfaces (of air side) of the insulating board 21 and the insulating board 31 as shown in FIGS. 4 and 5. Specifically, the epoxy resin adhesive is infused onto the insulating substrates 21 and 31 through a dispenser, and then the insulating substrates 21 and 31 are arranged in a high temperature sink so that the adhesives are hardened. Thus, the adhesive layer 27 and the adhesive layer 37 are formed. In this embodiment, the adhesive layer 27, 37 can be provided with a thickness of about 2 mm-3 mm, for example.

Furthermore, as shown in FIGS. 1-4, an adhesive can be applied to the gaps 17 (at periphery portions of insulating substrates 21 and 31) between the thermoelectric element substrate unit 10 and the insulating board 21, 31 too, so that a seal for restricting the intrusion of water and the like to the side of the thermoelectric element substrate unit 10 is provided.

Thereafter, the case member 28 and the case member 38 are arranged to cover the thermoelectric conversion module 200, and respectively positioned at the two opposite sides (e.g., upper side and lower side in FIG. 1) of the thermoelectric conversion module 200, so that the blown air passage where air flows is formed. In this case, a packing (not shown) is filled in the gap between the tip portion (fixing member 23) of the electrode member 22 and the case member 28 and the gap between the tip portion (fixing member 33) of the electrode member 32 and the case member 38, so that the position of the thermoelectric conversion module 200 in the case member 28 and the case member 38 is fixed.

Thus, in the thermoelectric conversion device 100, the insulating film 40 is formed by electrodeposition coating at the substantially whole surface of the conductive part where the potential is applied when the voltage is applied to the connection terminals 24a and 24b. In this case, the thermoelectric conversion module 200 is firstly constructed, and then the electrodeposition coating is performed at the thermoelectric conversion module 200 so that the insulating film 40 can be selectively formed at the conductive part where the insulation is necessary. Moreover, the substantially whole surface of the conductive part where the insulation is necessary can be provided with the insulating film 40 at a same stage. Because the electrodeposition coating is provided, the insulating film 40 where the pin holes are reduced can be substantially formed at the heat exchanging portion 26 and the heat exchanging portion 36 or the like which have a complex shape, thus restricting the short circuit due to the contact between the heat exchanging portions 26 and 36 which are adjacent to each other and restricting ion-migration which is caused by water droplet and the like adhered due to condensation when air is cooled.

Furthermore, in the thermoelectric conversion device 100 according to this embodiment, the adhesive layer 27, 37 is formed at the vicinity of the exposure portion 42 of the heat exchanging portion 26, 36 where it is difficult to form the insulating film 40 by the electrodeposition coating, in such a manner that the adhesive layer 27, 37 covers the exposure portion 42 from the outer side of the insulating film 40. Thus, the insulating film 40 is reinforced, so that the insulation of the conductive part (in the thermoelectric conversion device 100) where the insulation is necessary can become substantially complete. Therefore, the ion-migration and the short circuit in the thermoelectric conversion device 100 can be substantially restricted.

Moreover, the adhesive layer 27, 37 is constructed of the epoxy resin adhesive, so that the cost can be reduced. Because there are various epoxy resin adhesives having flexibility, the adhesive layer 27, 37 can be constructed of a suitable adhesive.

Because the adhesive layers 27 and 37 are respectively arranged to seal the gap between the adhesive layer 27 and the heat exchanging portion 26 and the gap between the adhesive layer 37 and the heat exchanging portion 36, water droplet adhered to the heat exchanging portions 26 and 36 due to condensation when air is cooled can be substantially restricted from intruding upon the side of the thermoelectric elements 12 and 13. Therefore, the short circuit at the side of the thermoelectric elements 12 and 13 and the ion-migration can be substantially restricted.

Furthermore, in this case, the adhesive layer 27, 37 is formed to cover the substantially whole surface (of the side of air) of the insulating board 21, 31. Thus, the adhesive is poured to the substantially whole surface of the insulating board 21, 31 with respect to the exposure portion 42 exposed to the air side of the heat exchanging portion 26, 36, so that the adhesive layer 27, 37 can be formed once (that is, at a single step). Therefore, it is unnecessary to apply the adhesive to the portions one by one.

### Second Embodiment

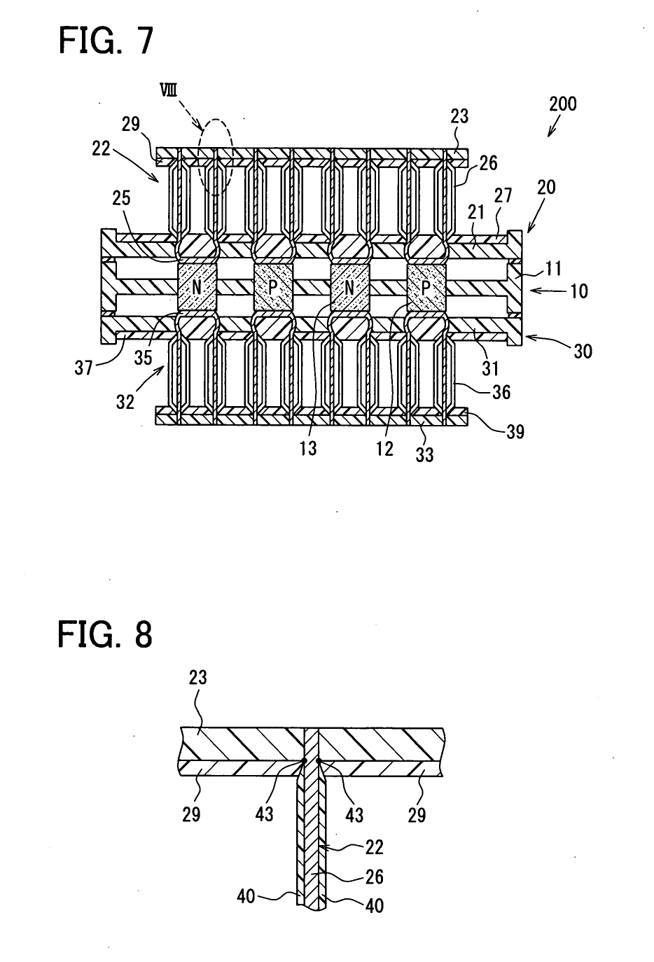

A second embodiment of the present invention will be described with reference to FIGS. 7 and 8. In the above-described first embodiment, the adhesive layers 27 and 37 are respectively arranged at the surfaces of the insulating substrates 21 and 31 where the roots portions of the electrode members 22 and 32 are respectively held. According to the second embodiment, as show in FIG. 7, in addition to the adhesive layers 27 and 37, a third adhesive layer 29 and a fourth adhesive layer 39 are respectively arranged at the surfaces of the fixing member 23 and the fixing member 33 where the tip portions of the electrode members 22 and 32 are held.

The third adhesive layer 29 is formed at the substantially whole of the surface (of the side of heat exchanging portion 26) of the fixing member 23, and the fourth adhesive layer 39 is formed at the substantially whole of the surface (of the side of heat exchanging portion 36) of the fixing member 33. In this embodiment, the adhesive layer 29, 39 can be provided with a thickness of about 0.5 mm-1 mm, for example.

With reference to FIGS. 7 and 8, the third adhesive layer 29 arranged at the surface of the fixing member 23 is provided at the contact portion between the tip portion of the heat exchanging portion 26 and the fixing member 23, in such a manner that the third adhesive layer 29 covers the insulating film 40 from the outer side of an exposure portion 43 which is exposed to the air side of the heat exchanging portion 26 (when being viewed at the stage before third adhesive layer 29 is formed). Thus, insulation of the part where it is difficult to form the insulating film 40 at the heat exchanging portion 26 by the electrodeposition coating can be reinforced to become substantially complete.

The exposure portion 43 of the side of the heat exchanging portion 36 has the similar construction to the exposure portion 43 of the heat exchanging portion 26 shown in FIG. 8, and the fourth adhesive layer 39 can be provided with the same construction as the third adhesive layer 29.

The third adhesive layer 29 and the fourth adhesive layer 39 can be formed together with the adhesive layer 27 and the adhesive layer 37 at the adhesive layer forming process which is performed similarly to the first embodiment. Specifically, an epoxy resin seal material is applied to the surfaces of the fixing members 23 and 33, and then the fixing members 23 and 33 are hardened so that the third adhesive layer 29 and the fourth adhesive layer 39 are formed.

According to this embodiment, the third adhesive layer 29 and the fourth adhesive layer 39 are respectively provided at the substantially whole surfaces (of the sides of electrode members 22 and 32) of the fixing member 23 and the fixing member 33 where the tip portions of the electrode member 22 and the electrode member 32 are held, thus reinforcing the insulation of the vicinity of the exposure portion 43 (at the fixing member 23, 33 positioned at the tip portion of the electrode member 22, 32) where it is difficult to form the insulating film 40 by the electrodeposition coating. Therefore, the insulation at the side of the tip portion of the electrode member 22, 32 can become substantially complete. Accordingly, the short circuit in the thermoelectric conversion device 100 and the ion-migration can be substantially restricted.

About the thermoelectric conversion device 100 and the manufacture method thereof, what has not been described in the second embodiment can be the same with the first embodiment.

### Third Embodiment

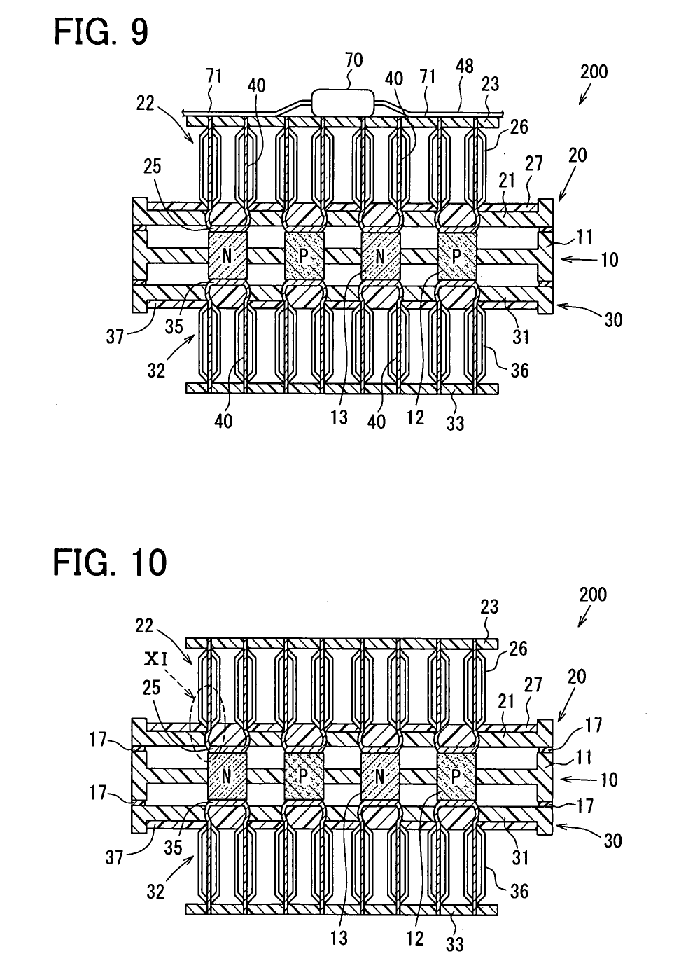

A third embodiment of the present invention will be described with reference to FIG. 9. According to this embodiment, a temperature sensor 70 (for example, thermistor) is additionally arranged at the surface (of opposite side to electrode member 22) of the fixing member 23.

The thermistor 70 is arranged at the fixing member 23 to contact the tip portion of the electrode member 22. A lead 71 (wiring) for connecting the thermistor 70 with an exterior control unit (not shown) is arranged at the fix member 23. The lead 71 can be constructed of a conductive metal wire, for example. An insulating film 48 (wiring insulation layer) is formed at the surface of the lead 71 by the electrodeposition coating, for example.

The thermistor 70 can be fixed to the fixing member 23 by an adhesive or the like and the lead 71 can be joined to the fixing member 23 by soldering or the like, at the module constructing process similar to the first embodiment.

Thus, at the insulation layer forming process similar to the first embodiment, when the insulating film 40 is formed at the thermoelectric conversion module 200, the voltage is applied not only to the one connection terminal (which is used as negative pole and not shown) of the thermoelectric conversion module 200, but also to the lead 71 (which is used as negative pole) of the thermistor 70. Accordingly, because the electrodeposition coating is performed, the insulating film 48 can be also formed at the lead 71 of the thermistor 70 concurrently with the forming of the insulating film 40 at the conductive portion of the thermoelectric conversion module 200.

In this embodiment, the thermistor 70 can be arranged to contact the electrode member 22. However, the arrangement position of the thermistor 70 is not limited. For example, the thermistor 70 can be also positioned in the vicinity of the electrode member 22, or positioned at the side of the electrode member 32, according to the need.

Thus, in the case where the thermoelectric conversion module 200 is provided with the thermistor 70 and the lead 71, the insulating film 48 can be concurrently formed at the lead 71 of the thermistor 70 which is arranged at the thermoelectric conversion module 200 when the insulating film 40 is formed at the surface of the conductive part of the thermoelectric conversion module 200 by the electrodeposition coating. Therefore, the ion-migration and the short circuit in the thermoelectric conversion device 100 can be substantially restricted, even when water intrudes upon the lead 71.

About the thermoelectric conversion device 100 and the manufacture method thereof, what has not been described in the third embodiment can be the same with the first embodiment.

### Fourth Embodiment

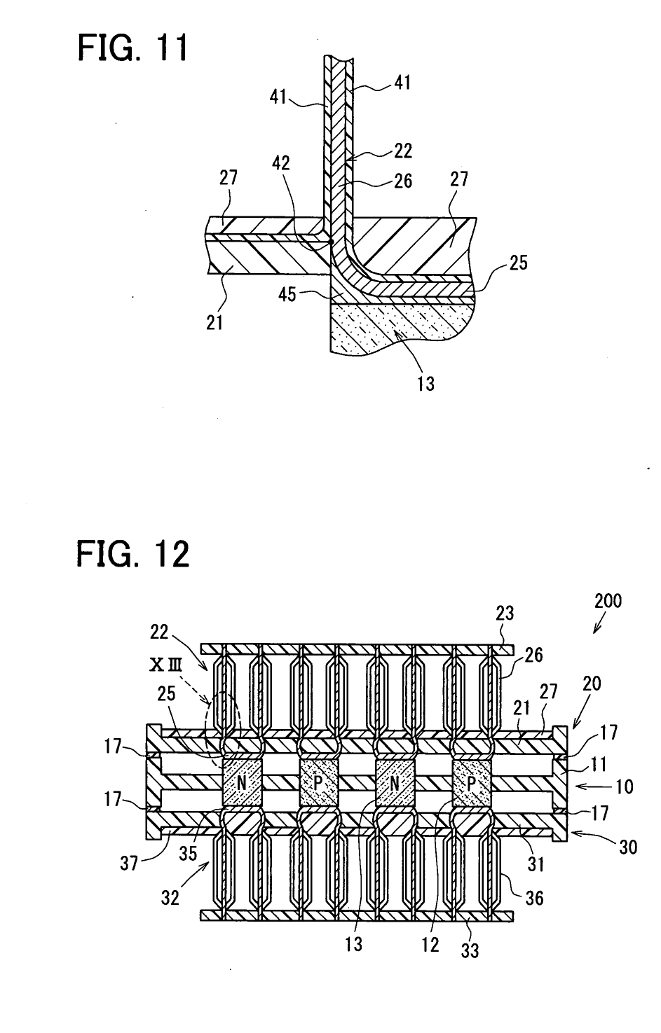

A fourth embodiment of the present invention will be described with reference to FIGS. 10 and 11. In this case, the insulating film is changed as compared with the first embodiment.

According to the fourth embodiment, an insulating film 41 is formed by coating a resin film by vapor deposition at the substantially whole surface of the thermoelectric conversion module 200, in such a state that the thermoelectric element substrate unit 10, the electrode board unit 20 and the electrode board unit 30 are assembled to have the shape of the thermoelectric conversion module 200. That is, after the thermoelectric conversion module 200 is arranged in an vapor deposition sink and the vapor deposition sink is made vacuum, vapor of polyimide resin or the like is filled into the vapor deposition sink so that the polyimide film is provided by the coating. That is, the insulating film 41 is formed.

Similarly to the insulating film 40 formed by the electrodeposition coating described in the first embodiment, whether or not the insulating film 41 is formed at the inner surface (that is, side surfaces of thermoelectric elements 12, 13 and side surface of joining portion 45) of the thermoelectric conversion module 200 is determined by whether or not the vapor deposition of the insulating film 41 is performed before the process for sealing the outer periphery portion of the thermoelectric conversion device 100 by sealing the gap 17 of the adhesive.

As compared with the insulating film 40 formed by the electrodeposition coating described in the first embodiment, the insulating film 41 is formed at the substantially whole surfaces of (of air side) of the insulating substrates 21 and 31 and formed at the surfaces of the heat exchanging portions 26 and 36. The portion of the insulating film 41 at the insulating board 21 (31) is continuous with and substantially orthogonal to the portion of the insulating film 41 at the heat exchanging portion 26 (36).

In this embodiment, the adhesive layer 27, 37 is formed at the outer side of the insulating film 41, similarly to the first embodiment. The adhesive layer 27 (37) is formed at the whole surface of the air side of the insulating board 21 (31) and the inner surface of the heat exchanging portion 26 (36), in such a manner that the adhesive layer 27 (37) covers the vicinity of the exposure portion 42 of the heat exchanging portion 26 (36). Similarly to the first embodiment, the exposure portion 42 means the portion of the heat exchanging portion 26, 36 (which contacts insulating board 21, 31) which is exposed to the air side when being viewed before the adhesive layer 27, 37 is formed.

In this case, in the insulating film 41 which is continuously formed at the surfaces of the insulating board 21 (31) and the heat exchanging portion 26 (36), there easily occurs at the vicinity of the exposure portion 42 a stress due to vibration in the environment where the thermoelectric conversion device is used and a stress due to a heat-cool repeat when the temperature varies. Thus, crack may occur. Therefore, water droplet generated at the heat exchanging portion 26, 36 may reach the thermoelectric element 12, 13 to cause the short circuit and the ion-migration.

However, according to this embodiment, because the adhesive layer 27 and the adhesive layer 37 are arranged to cover the vicinity of the exposure portion 42 from the outer side, the insulating film 41 is reinforced so that the crack can be restricted. Therefore, the short circuit the ion-migration can be reduced. Particularly, in the case where the adhesive layer 27, 37 is constructed of a flexible adhesive, the crack can be substantially restricted.

About the thermoelectric conversion device 100 and the manufacture method thereof, what has not been described in the fourth embodiment can be the same with the first embodiment.

### Fifth Embodiment

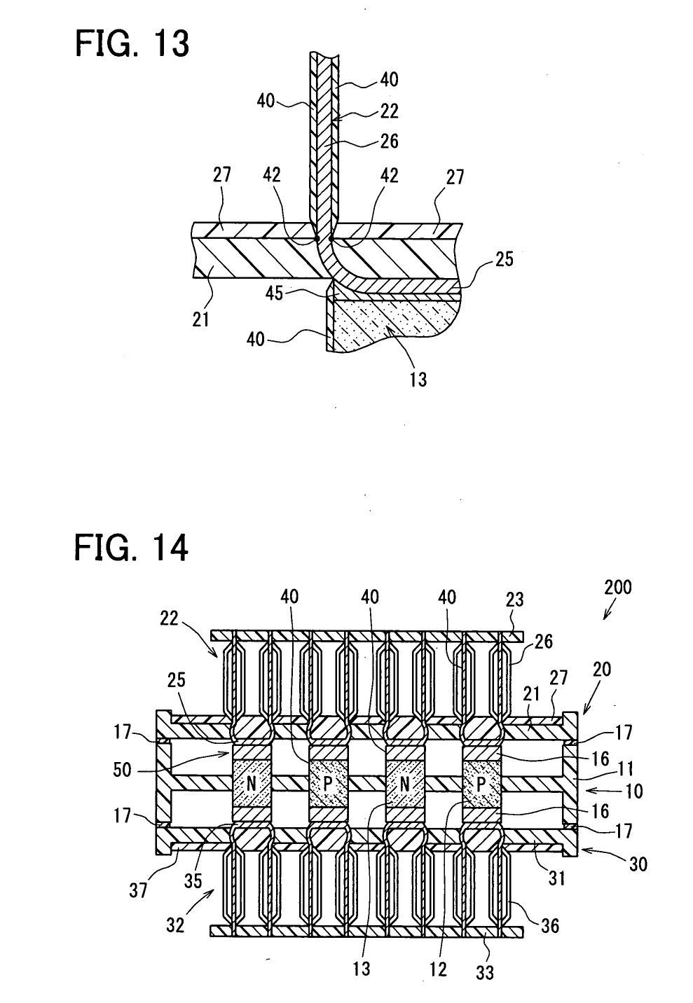

A fifth embodiment of the present invention will be described with reference to FIGS. 12 and 13. According to the fifth embodiment, the assembling method of the insulating board 21, 31 with the electrode member 22, 32 is changed.

In this embodiment, the insulating board 21 (31) is formed integrally with the electrode member 22 (32) by insertion molding. Thus, the insulating board 21 (31) is also arranged at the inner side of the electrode member 22 (32) having the substantially U-like shape, to have a plate shape where it is unnecessary to provide the engagement hole for holding the electrode member 22 (32).

The insulating film 40 is formed at the substantially whole surfaces of the heat exchanging portions 26 and 36 (of electrode members 22 and 32) at the air side of the insulating substrates 21 and 31, by the electrodeposition coating. As above described, because the insulating board 21 (31) is formed integrally with the electrode member 22 (32) by the insertion molding, the exposure portions 42 at the heat exchanging portion 26 (36) are respectively formed at the outer side and the inner side of the electrode member 22 (32).

In this case, the adhesive layer 27 (37) is formed at the whole surfaces (of air side) of the insulating board 21 (31), and the two exposure portions 42 are covered by the adhesive layer 27 (37) from the outer side. Thus, the insulation of the exposure portions 42 in the vicinity of the insulating board 21, 31 where it is difficult to form the insulating film 40 at the heat exchanging portion 26, 36 by the electrodeposition coating can be reinforced by the adhesive layer 27, 37 to become complete.

In this embodiment, the insulating board 21 and the insulating board 31 are respectively integrated with the electrode member 22 and the electrode member 32 by the insertion molding. The resin material for molding the insulating board 21 (31) adheres to the surface of the electrode member 22 (32) due to an anchor effect to seal the part between the insulating board 21 (31) and the electrode member 22 (32). Therefore, it is unnecessary to seal the part between the insulating board 21 (31) and the electrode member 22 (32) additionally.

About the thermoelectric conversion device 100 and the manufacture method thereof, what has not been described in the fifth embodiment can be the same with the first embodiment.

### Sixth Embodiment

A sixth embodiment of the present invention will be described with reference to FIG. 14. In the above-described embodiments, the thermoelectric element 12 and the thermoelectric element 13 are directly connected with each other by the electrode portion 25 of the electrode member 22 and the electrode portion 35 of the electrode member 32. According to the sixth embodiment, as shown in FIG. 14, an electrode portion 16 other than the electrode members 22 and 32 can be arranged to connect the thermoelectric element 12 with the thermoelectric element 13 which are adjacent to each other.

In this case, each of the electrode portion 25 of the electrode member 22 and the electrode portion 35 of the electrode member 32 is joined to the electrode portion 16. Specifically, in the module constructing process similar to what is described in the first embodiment, the electrode portions 16 are respectively joined by soldering to the upper end surface and the lower surface of the thermoelectric element 12 and those of the thermoelectric element 13 after the thermoelectric element 12 and the thermoelectric element 13 are attached to the insulating substrate 11.

Thus, the manufacture of the thermoelectric element substrate unit 10 is finished. Then, when the electrode board unit 20 and the electrode board unit 30 are joined to the thermoelectric element substrate unit 10 to construct the thermoelectric conversion module 200, the electrode portion 25 of the electrode member 22 and the electrode portion 35 of the electrode member 32 are joined to the electrode portions 16. The electrode portion 16 can be constructed of a conductive metal such as copper or the like and have a substantially plate shape, for example.

Then, the thermoelectric conversion module 200 can be provided with the electrodeposition coating similarly to the insulation layer forming process of the first embodiment. Thus, the insulating film 40 is formed at the surfaces of the heat exchanging portions 26 and 36 and the side surfaces of the thermoelectric elements 12 and 13. Furthermore, the insulating film 40 is also formed at the side surface of the solder joining portion between the electrode portion 16 and the thermoelectric element 12 and that between the electrode portion 16 and the thermoelectric element 13, the side surface of the electrode portion 16, the side surface of the solder joining portion between the electrode portion 16 and the electrode portion 25 of the electrode member 22 and that between the electrode portion 16 and the electrode portion 35 of the electrode member 32.

According to this embodiment, the electrode portion 16 other than the electrode member 22 and the electrode member 32 are provided. Because the series circuit 50 has been constructed due to the connection of the thermoelectric element 12 with the thermoelectric element 13 through the electrode portion 16 when the manufacture of the thermoelectric element substrate unit 10 is finished, an electrical inspection of the series circuit 50 and a faulty conduction and the like between the electrode portion 16 and the thermoelectric element 12, 13 can be readily performed for the thermoelectric element substrate unit 10 before the thermoelectric conversion module 200 are assembled.

### Other Embodiment

Although the present invention has been fully described in connection with the preferred embodiments thereof with reference to the accompanying drawings, it is to be noted that various changes and modifications will become apparent to those skilled in the art.

In the first embodiment, the two end portions (root portion and tip portion) of the electrode member 22 are respectively fixed to the insulating board 21 and the fixing member 23, and those of the electrode member 32 are respectively fixed to the insulating board 31 and the fixing member 33. However, the fixing member 23 and the fixing member 33 can be also omitted. In this case, the electrode member 22 and the electrode member 32 are respectively held by the insulating board 21 and the insulating board 31 only at the root portions thereof which are fixed to the insulating substrates 21 and 31. Alternatively, the insulating substrates 21 and 31 can be also omitted. In this case, the electrode member 22 and the electrode member 32 are respectively held by the fixing member 23 and the fixing member 33 only at the tip portions thereof which are fixed to the fixing member 23 and the fixing member 33.

In the above-described embodiments, the thermoelectric elements 12 and 13 are held at the insulating substrate 11 (holding member) to construct the thermoelectric element substrate unit 10. Alternatively, the insulating substrate 11 can be also omitted. In this case, for example, the thermoelectric element 12, 13 can be joined to one of the electrode portion 25 of the electrode member 22 and the electrode portion 35 of the electrode member 32.

In the above-described embodiments, the heat exchanging portion 26 of the electrode member 22 and the heat exchanging portion 36 of the electrode member 32 are formed to have the louver shape. However, the heat exchanging portion 26 and the heat exchanging portion 36 can also have an offset shape. Alternatively, corrugated fins each of which is constructed of a corrugated metal plate or the like can be provided in each of the electrode member 22 and the electrode member 32 which have a comb teeth shape, to construct the heat exchanging portion 26 and the heat exchanging portion 36.

In the above-described embodiments, the positive terminal of the direct current power source is connected with the connection terminal 24a, and the negative terminal thereof is connected with the connection terminal 24b. Alternatively, the positive terminal of the direct current power source can be also connected with the connection terminal 24b, and the negative terminal thereof can be also connected with the connection terminal 24a. In this case, the electrode member 22 of the upper side constructs a heat radiating portion, and the electrode member 32 of the lower side constructs a heat absorbing portion.

That is, the heat absorbing side and the heat radiating side can be switched, by switching the flowing direction of the current flowing in the series circuit 50 constructed of the thermoelectric elements 12 and 13. Thus, the thermoelectric conversion device can be used to cool a heat-producing component such as a semiconductor or electrical component or the like, and cool/heat in an air conditioning device.

Moreover, in the above-described embodiments, the insulating film 40 (electrodeposition coating layer) formed by the electrodeposition coating or the insulating film 41 (vapor deposition layer) formed by vapor deposition is provided as the insulating film. Alternatively, the thermoelectric conversion module can be also immersed in the insulating paint, and then the thermoelectric conversion module is heated and dried so that the insulating film (paint layer) is formed at the surfaces of the heat exchanging portion 26 and the heat exchanging portion 36.

Moreover, the adhesive layer 27 and the adhesive layer 37 can be also constructed of a silicon adhesive.

Furthermore, in the above-described embodiments, the adhesive layers 27 and 37 are formed to respectively cover the substantially whole surface of the insulating board 21 and that of the insulating board 31. However, the adhesive layers 27 and 37 can be also respectively pin-point formed in the vicinity of the exposure portion 42 of the heat exchanging portion 26 and that of the heat exchanging portion 36.

Such changes and modifications are to be understood as being in the scope of the present invention as defined by the appended claims.

What is claimed is:

1. A thermoelectric conversion device, comprising:
a series circuit including a plurality of P-type thermoelectric elements and a plurality of N-type thermoelectric elements which are alternately arranged and electrically connected with each other in series by a plurality of electrode portions;
a plurality of heat-exchanging portions for heat-exchanging with a heat transfer media, the heat-exchanging portions being directly connected with the electrode portions;
an insulating board from which the heat-exchanging portions protrude to be held, the heat-exchanging portions being electrically insulated from each other by the insulating board,
the heat transfer media flowing through protrusion sides of the heat-exchanging portions with respect to the insulating board;
an insulating layer which is electrically insulating and arranged at least a substantially whole surface of the protrusion side of each of the heat-exchanging portions; and
an adhesive layer, wherein
the heat-exchanging portions contact the insulating board, and the adhesive layer covers exposure portions of the heat-exchanging portions from an outer side of the insulating layer, the exposure portions being exposed to a side of the heat transfer media.

2. The thermoelectric conversion device according to claim 1, wherein
the insulating layer is an electrodeposition coating layer formed by electrodeposition coating.

3. The thermoelectric conversion device according to claim 1, wherein
the insulating layer is a vapor deposition layer which is formed by vapor deposition.

4. The thermoelectric conversion device according to claim 1, wherein
the insulating layer is a paint layer constructed of an insulating paint.

5. The thermoelectric conversion device according to claim 1, wherein
the adhesive layer is constructed of one of an epoxy adhesive and a silicon adhesive.

6. The thermoelectric conversion device according to claim 1, wherein
the adhesive layer is arranged to substantially seal a gap between the heat-exchanging portion and the insulating board.

7. The thermoelectric conversion device according to claim 1, wherein
the adhesive layer covers a substantially whole surface of the insulating board, the surface being at the protrusion side of the heat-exchanging portion.

8. The thermoelectric conversion device according to claim 1, wherein
the insulating board constructs a first holding member for holding the heat-exchanging portions at a connection side where the heat-exchanging portion is connected with the electrode portion.

9. The thermoelectric conversion device according to claim 8, further comprising
a second holding member which is electrically insulating and holds the heat-exchanging portions at a side opposite to the connection side where the heat-exchanging portion is connected with the electrode portion.

10. The thermoelectric conversion device according to claim 1, further comprising:
a temperature sensor which is arranged at one of a position where the temperature sensor contacts the heat-exchanging portions and a position in the vicinity of the hear-exchanging portions;
a wiring which is connected with the temperature sensor; and
a wiring insulating layer which is electrically insulating and arranged at a substantially whole surface of the wiring.

11. The thermoelectric conversion device according to claim 10, wherein
the wiring insulating layer is an electrodeposition coating layer formed by electrodeposition coating.

12. The thermoelectric conversion device according to claim 1, wherein
the plurality of the electrode portions are respectively formed integrally with the plurality of the heat-exchanging portions.

13. A manufacture method for a thermoelectric conversion device which has a series circuit, an insulating board and a plurality of heat-exchanging portions for heat-exchanging with a heat transfer media flowing through protrusion sides of the heat-exchanging portions with respect to the insulating board, the manufacture method comprising:
a module constructing step for constructing a thermoelectric conversion module having the series circuit including a plurality of P-type thermoelectric elements and a plurality of N-type thermoelectric elements which are alternately arranged and connected with each other in series by a plurality of electrode portions directly connected with the heat-exchanging portions, the heat-exchanging portions protruding from the insulating board to be held and being electrically insulated from each other by the insulating board;
an insulation layer forming step for forming an insulating layer which is electrically insulating and arranged at least a substantially whole surface of the protrusion side of each of the heat-exchanging portions; and
an adhesive layer forming step for forming an adhesive layer which covers exposure portions of the heat-exchanging portions from an outer side of the insulating layer, the exposure portion being exposed to a side of the heat transfer media, the heat-exchanging portions contacting the insulating board.

14. The manufacture method according to claim 13, wherein
in the insulation layer forming step, the insulating layer is formed by electrodeposition coating.

15. The manufacture method according to claim 13, wherein
in the insulation layer forming step, the insulating layer is formed by vapor deposition.

16. The manufacture method according to claim 13, wherein
in the insulation layer forming step, the insulating layer is formed by applying an insulating paint.

17. The manufacture method according to claim 13, wherein
in the adhesive layer forming step, the adhesive layer is constructed of one of an epoxy adhesive and a silicon adhesive.

18. The manufacture method according to claim 13, wherein
in the adhesive layer forming step, the adhesive layer is arranged to seal a gap between the heat-exchanging portion and the insulating board.

19. The manufacture method according to claim 13, wherein
in the adhesive layer forming step, the adhesive layer is arranged to cover a substantially whole surface of the insulating board, the surface being at the protrusion side of the heat-exchanging portion.

20. The manufacture method according to claim 13, wherein
in the module constructing step, the thermoelectric conversion module is constructed to have the insulating board as a first holding member which holds the heat-exchanging portions at a connection side where the heat-exchanging portion is connected with the electrode portion.

21. The manufacture method according to claim 20, wherein
in the module constructing step, the thermoelectric conversion module is constructed to have a second holding member which holds the heat-exchanging portions at a side opposite to the connection side where the heat-exchanging portion is connected with the electrode portion.

22. The manufacture method according to claim 13, wherein:
in the module constructing step, the thermoelectric conversion module is constructed to have a temperature sensor and a wiring which is connected with the temperature sensor, the temperature sensor being arranged at one of a position where the temperature sensor contacts the heat-exchanging portions and a position in the vicinity of the hear-exchanging portions; and
in the insulation layer forming step, a wiring insulating layer for insulating is formed at a substantially whole surface of the wiring, along with the forming of the insulating layer.

23. The manufacture method according to claim 22, wherein
in the insulation layer forming step, the wiring insulating layer is formed by electrodeposition coating.

24. The manufacture method according to claim 22, wherein
the plurality of the electrode portions are respectively formed integrally with the plurality of the heat-exchanging portions.

25. The manufacture method according to claim 13, wherein
in the module constructing step, the thermoelectric conversion module is constructed to further have a holding member which holds the heat-exchanging portions at a side opposite to the connection side where the heat-exchanging portion is connected with the electrode portion.

26. The thermoelectric conversion device according to claim 1, further comprising
a holding member which is electrically insulating and holds the heat-exchanging portions at a side opposite to a connection side where the heat-exchanging portion is connected with the electrode portion.
